(19) United States
(12) Patent Application Publication
(10) Pub. No.: US 2023/0079122 A1
(43) Pub. Date: Mar. 16, 2023

(54) DISPLAY DEVICE AND DISPLAY APPARATUS

(71) Applicant: LG DISPLAY CO., LTD., SEOUL (KR)

(72) Inventors: Junjae LEE, Paju-si (KR); Myeongah Shin, Seoul (KR)

(73) Assignee: LG DISPLAY CO., LTD., SEOUL (KR)

(21) Appl. No.: 17/880,977

(22) Filed: Aug. 4, 2022

(30) Foreign Application Priority Data
Sep. 13, 2021 (KR) 10-2021-0121448

(51) Int. Cl. H01L 51/00; H01L 51/52; B32B 3/30; B32B 5/18; B32B 5/32

(52) U.S. Cl. CPC H01L 51/0097; B32B 3/30; B32B 5/18; B32B 5/32; H01L 51/529; B32B 7/12; H01L 2251/5338

(57) ABSTRACT

A display device includes a cover member, a display panel disposed on one surface of the cover member, and a cushion plate disposed on one surface of the display panel, wherein the cushion plate includes a cushion layer, a conductor, and a heat-dissipation layer, wherein the cushion layer and the conductive layer are disposed between the display panel and the heat-dissipation layer, wherein the conductor is disposed in an edge area of the cushion plate.

### CROSS-REFERENCE TO RELATED APPLICATION

This application claims the priority of Korean Patent Application No. 10-2021-0121448 filed on Sep. 13, 2021, which is hereby incorporated by reference in its entirety.

### BACKGROUND

### Field of the Disclosure

The present disclosure relates to a display device and a display apparatus, and more particularly, to provide a display device and a display apparatus capable of reducing occurrence of a brighter phenomenon and a greenish phenomenon at a distal end of a display panel.

### Description of the Background

Display apparatuses are implemented in a variety of forms, such as televisions, monitors, smart phones, tablet PCs, laptops, and wearable devices.

In general, a display apparatus includes a display area for displaying a screen and a non-display area formed along an outer edge of the display area.

In the display apparatus, the non-display area is also referred to as a bezel area. When the bezel area is thick, the user’s gaze is dispersed. When the bezel area is thin, the user’s gaze may be fixed on the screen of the display area and thus immersion may be increased.

In other words, when the bezel area becomes thinner, an overall size of the display apparatus may be reduced while increasing the user’s immersion. Thus, demand from consumers for a display apparatus having the reduced bezel area as much as possible is increasing.

Electric charges may be generated on a surface of a display apparatus due to physical friction or the like.

When the electric charges generated in this way are not discharged to an outside through a ground path, the electric charges may be intensively accumulated on a side surface of a distal end of a display panel disposed in a bezel area of the display panel.

When the electric charges are accumulated in a specific area, an electric field may be generated in proportion to an amount of the accumulated electric charges.

Therefore, when the electric charges generated on the surface of the display apparatus are not effectively discharged to the outside, a strong electric field may be generated on the side surface of the distal end of the display panel.

When the strong electric field is generated on the side surface of the distal end of the display panel, a brighter phenomenon in which a side area of the distal end becomes brighter compared to a display area of the display panel and a greenish phenomenon in which a partial area becomes green may occur.

When the brighter phenomenon and the greenish phenomenon occur at the distal end of the display panel, this may lead to a quality defect of the display panel.

In one example, a charging solution may be applied to form a charge movement path to discharge the electric charges of the display apparatus to the outside.

However, since the charge movement path formed by applying the charging solution is in contact with a side surface of the display panel, some of the electric charges cannot be discharged to the outside and may flow into the display panel.

Further, since a separate process of applying the charging solution is required for forming the charge movement path, efficiency of a manufacturing process of the display apparatus may be reduced.

In addition, the charging solution is applied so as to be exposed out of the display device. Thus, the applied charging solution may be damaged in a handling process during a manufacturing process of a display device such that a charging function may be lost.

### SUMMARY

Accordingly, the present disclosure is directed to a display device and a display apparatus that substantially obviates one or more of problems due to limitations and disadvantages described above.

More specifically, the present disclosure is to provide a display device and a display apparatus that can reduce the occurrence of the brighter phenomenon and the greenish phenomenon at the distal end of the display panel, and may improve the process efficiency and may reduce the loss of the charging function.

The present disclosure is also to provide a display device and a display apparatus capable of reducing the occurrence of the brighter phenomenon and the greenish phenomenon at the distal end of the display panel.

The present disclosure is also to provide a display device and a display apparatus in which an amount by which electric charges of a cover member flow into an inside of the display panel may be reduced, and a significant amount of the electric charges thereof may be effectively discharged to the outside.

The present disclosure is also to provide a display device and a display apparatus capable of increasing efficiency of a process for forming a charge movement path.

Further, the present disclosure is to provide a display device and a display apparatus capable of reducing loss of a charging function resulting from damage to a charge movement path due to an external factor such as physical contact.

The present disclosure is not limited to the above-mentioned. Other features and advantages of the present disclosure that are not mentioned may be understood based on following descriptions, and may be more clearly understood based on aspects of the present disclosure. Further, it will be easily understood that the purposes and advantages of the present disclosure may be realized using means shown in the claims and combinations thereof.

A display device according to an aspect of the present disclosure includes a cover member, a display panel disposed on one surface of the cover member, and a cushion plate disposed on one surface of the display panel, wherein the cushion plate includes a cushion layer, a conductor, and a heat-dissipation layer, wherein the cushion layer and the conductor are disposed between the display panel and the heat-dissipation layer, wherein the conductor is disposed in an edge area of the cushion plate.

A display device according to an aspect of the present disclosure includes a cover member, a display panel disposed on one surface of the cover member, and a cushion plate including at least one conductor disposed in an edge area thereof and having a lower resistance than that of the display panel, wherein the cushion plate is disposed one surface of the display panel.

A display apparatus according to an aspect of the present disclosure includes the display device according to an aspect of the present disclosure, and a casing disposed on a back surface of the display device and supporting the cover member.

According to an aspect of the present disclosure, the conductor is disposed in the edge area of the cushion plate disposed on the back surface of the display panel, such that an electric field may be induced so that the electric charges of the cover member may move to the conductor, thereby forming the charge movement path.

Accordingly, concentration of the electric charges on the side surface of the display panel may be reduced, thereby reducing the brighter phenomenon and the greenish phenomenon that may otherwise intensively occur in a partial area of a side portion of the display panel.

Further, the conductor constitutes the charge movement path in an air contact manner such that the electric charges of the cover member move to the conductor without direct contact with a side surface of each of the cover member and the display panel, thereby reducing an amount by which the electric charges of the cover member enters the inside of the display panel through the side surface of the display panel, and allowing a significant amount of the electric charges to be discharged to the outside effectively.

Further, the conductor constituting the charge movement path is included in the cushion plate. Thus, a separate additional process for forming the charge movement path after forming the cushion plate is not required, so that the efficiency of the process may be improved.

Further, the conductor constituting the charge movement path is received in the cushion plate, thereby reducing the loss of the charging function resulting from the damage to the charge movement path due to the external factor such as physical contact.

Effects of the present disclosure are not limited to the above-mentioned effects, and other effects as not mentioned will be clearly understood by those skilled in the art from following descriptions.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1A and FIG. 1C respectively show a front surface and a back surface of a display apparatus according to an aspect of the present disclosure, and FIG. 1B shows a back surface of a display device in a state in which a casing is removed;

FIG. 2 is a cross-sectional view in I-I’ direction of the display device according to an aspect of the present disclosure;

FIG. 3 is a cross-sectional view in II-II’ direction of the display device according to an aspect of the present disclosure;

FIG. 4 is a cross-sectional view in II-II’ direction of a display device according to another aspect of the present disclosure;

FIG. 5A and FIG. 5B are plan views of back surfaces of cushion plates according to various aspects of the present disclosure, respectively; and

FIG. 6A to FIG. 6E are cross-sectional views in III-III’ direction of display devices according to various aspects of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed below, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the aspects of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The display apparatus according to the present disclosure may be applied to an organic light-emitting display apparatus. The disclosure is not limited thereto. The display apparatus according to the present disclosure may be applied to various display apparatuses such as a micro LED display apparatus or a quantum dot display apparatus.

Hereinafter, a display apparatus according to an aspect of the present disclosure will be described in detail with reference to the drawings.

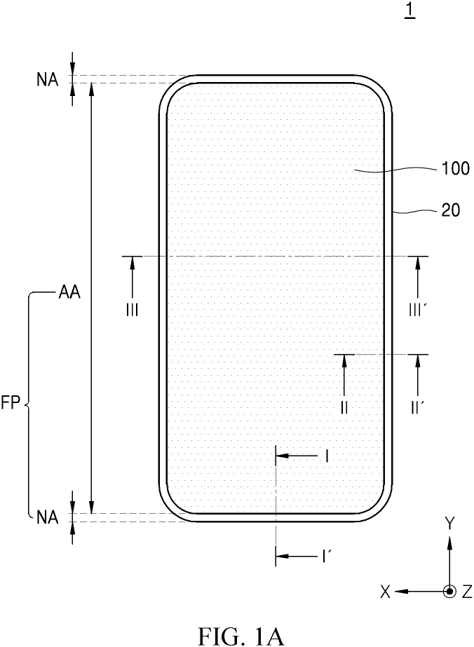

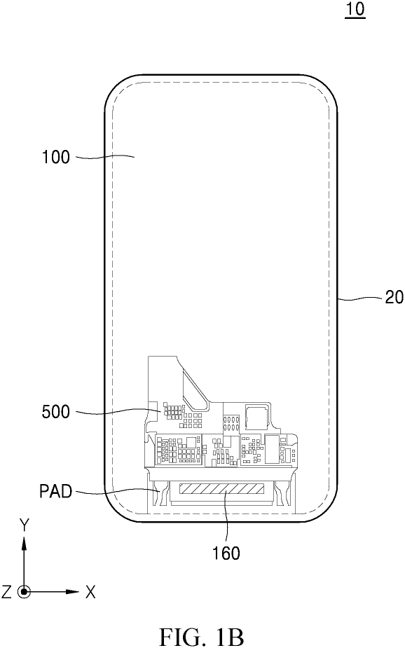

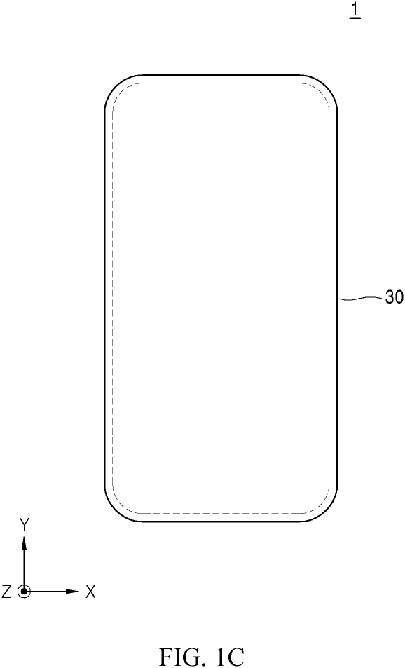

FIG. 1A and FIG. 1C respectively show front and back surfaces of the display apparatus according to an aspect of the present disclosure, and FIG. 1B shows the back surface of the display apparatus in a state in which a casing is removed.

As used herein, each of frontward and upward directions may mean a Z-axis direction, and each of backward and downward directions may mean a -Z-axis direction.

A display apparatus 1 may include a display device 10 including a cover member 20 and a display panel 100 attached to a bottom of the cover member 20. A direction from a top to the bottom of the cover member may refer to the downward direction (-Z axis direction).

The cover member 20 may be disposed to constitute the front portion of the display apparatus 1 to protect the display apparatus 1 from external impact.

An edge portion of the cover member 20 may have a curved portion or a bent portion that is curved or bent toward the back surface of the display device 10.

Since the cover member 20 may be disposed to cover a side surface of the display device 10 of the display apparatus 1, the member 20 may protect the display panel 100 from external impact not only on the front surface of the display device 10 but also on a side surface thereof.

The cover member 20 may overlap the display area AA of the display panel that displays an image. For example, the cover member 20 may be made of a transparent plastic material that may transmit an image therethrough, or may be made of a cover glass of a transparent glass material. The present disclosure is not limited thereto.

A casing 30 for supporting the cover member 20 may be disposed on the back surface of the display device 10.

The casing 30 may serve as a housing that protects the rear surface of the display apparatus 1, and may function as a casing constituting the outermost shell of the display apparatus 1.

The casing 30 may be made of various materials such as plastic, metal, or glass.

A middle frame (not shown) may be additionally disposed between the cover member 20 and the casing 30.

The middle frame may be disposed on a back surface of the display device 10 and may accommodate therein the display device 10. The middle frame may contact the cover member 20 such that the middle frame supports the cover member 20.

The middle frame may serve as a housing that protects the rear surface of the display device 10.

The middle frame may have a structure in which the display device 1 is disposed on one surface of the display device 10, and additional components such as a battery to apply power to the display apparatus 1 is disposed on the other surface of the middle frame.

A front portion FP of the display panel 100 may be disposed on a bottom surface of the cover member 20.

The front portion FP may include a pixel array including a plurality of pixels having a plurality of light-emitting elements, and driving transistors, and signal lines transmitting a drive signal to the pixels, so that an image may be displayed from the front portion.

The front portion FP may include a display area AA (active area) where the image is displayed and a non-display area NA (non-active area) other than the display area AA. The non-display area NA may be formed as an edge area surrounding the display area AA.

The display area AA and the non-display area NA may be equally applied to the cover member 20.

An area of the cover member 20 through which the image transmits may be the display area AA thereof.

An area of the cover member 20 which surrounds the display area AA and through which the image does not transmit may be a non-display area NA thereof.

The non-display area NA may be defined as a bezel area.

The display panel 100 disposed under the cover member 20 may include a bent portion which extends from one side of the front portion FP thereof and is bent downwardly.

The bent portion may be disposed at the outermost part of the display panel 100, and thus may be easily exposed to external impact. The bent portion may be easily deformed or broken when the impact is applied thereto. Accordingly, a support member or a reinforcing member for protecting the bent portion may be added to absorb the impact.

Hereinafter, a structure of the display device 10 according to an aspect of the present disclosure will be described.

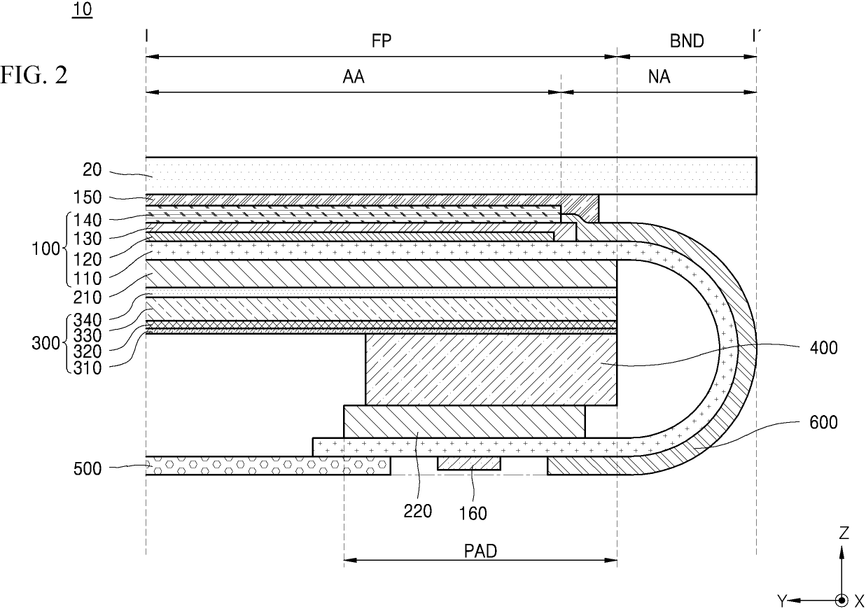

FIG. 2 is a cross-sectional view taken along a line I-I’ of the display device 10 according to an aspect of the present disclosure.

The display device 10 may include the cover member 20 as the topmost portion thereof and the display panel 100 disposed under the cover member 20.

The display device 10 may include the display panel 100 having the front portion FP, a bent portion BND, and a pad portion PAD bent from the bent portion BND so as to be disposed on a back surface of the front portion FP, a cushion plate 300 disposed between the front portion FP and the pad portion PAD, and disposed below the front portion FP, and a second connection member 400 to fix the pad portion PAD to the cushion plate 300.

A first back plate 210, the cushion plate 300, the second connection member 400, a second back plate 220, and the pad portion PAD may be sequentially disposed under the front portion FP of the display panel 100.

A first connection member 150 may be disposed between the cover member 20 and the display panel 100.

The first connection member 150 may connect or combine the cover member 20 and the display panel 100 to each other.

For example, the first connection member 150 may be a fixing member. The present disclosure is not limited to the term.

Since the first connection member 150 may be disposed to vertically overlap the display area AA, the member 150 may be made of a material through which the image of the display panel 100 may transmit.

For example, the first connection member 150 may be made of or may include a material such as OCA (Optical Clear Adhesive), OCR (Optical Clear Resin), or PSA (Pressure Sensitive Adhesive). However, the present disclosure is not limited thereto.

The display panel 100 disposed under the cover member 20 may include the front portion FP, the bent portion BND, and the pad portion PAD which constitute a display substrate 110.

The front portion FP of the display panel 100 may be disposed under the first connection member 150. For example, the front portion FP may be a portion where the image is displayed. The front portion may include the display substrate 110, a pixel array 120, an encapsulation portion 130, and a polarizing plate 140.

The bent portion BND of the display panel 100 may extend from one side of the front portion FP and be bent downwardly (in the -Z-axis direction) and then horizontally (in a Y-axis direction). The bent portion BND may include the display substrate 110 and the signal line.

The pad portion PAD of the display panel 100 may extend from the bent portion BND and be disposed under the front portion FP.

The pad portion PAD may include the display substrate 110, the signal line, and a pad electrode connected to the signal line. A driver circuit 160 or a flexible circuit board 500 for driving a pixel may be mounted on the pad electrode.

The polarizing plate 140 may be disposed on the top surface of the front portion FP and thus may be disposed on the top surface of the display panel 100. In addition, a functional layer for improving display performance of the display apparatus may be further disposed between the first connection member 150 and the polarizing plate 140.

The polarizing plate 140 prevents reflection of external light and improves the outdoor visibility and contrast ratio of the image displayed on the display panel 100.

The display panel 100 may include the display substrate 110, the pixel array 120 disposed on the display substrate 110, and the encapsulation portion 130 disposed to cover the pixel array 120.

A portion of the display substrate 110 may constitute a bottom of the display panel 100.

The display substrate 110 may constitute each of the front portion FP, the bent portion BND, and the pad portion PAD.

The display substrate 110 may be made of a flexible plastic material and may have flexible properties.

The display substrate 110 may include polyimide, or may be made of a thin glass material having flexibility.

The pixel array 120 may be disposed on the display substrate 110. The pixel array 120 may display an image. An area where the pixel array 120 may be disposed may be the display area AA.

Accordingly, an area of the cover member 20 corresponding to the pixel array 120 may be a display area AA of the cover member 20, while an area of the cover member 20 other than the display area AA may be a non-display area NA of the cover member 20.

The pixel array 120 may include light-emitting elements, thin-film transistors for driving the light-emitting elements, and the signal lines such as a gate line, a data line, and a pixel driving power line on the display substrate 110.

The pixel array 120 may include pixels that display images based on signals supplied to the signal lines. The pixel may include the light-emitting element and the thin-film transistor.

The light-emitting element may include an anode electrode electrically connected to the thin-film transistor, a light-emitting layer formed on the anode electrode, and a cathode electrode for supplying a common voltage.

The thin-film transistor may include a gate electrode, a semiconductor layer, a source electrode, and a drain electrode. The semiconductor layer of the thin-film transistor may include silicon such as a-Si, poly-Si, or low-temperature poly-Si, or oxide such as IGZO (Indium-Gallium-Zinc-Oxide). The present disclosure is not limited thereto.

The anode electrode may be disposed in each pixel area and in a corresponding manner to an opening area defined according to a pattern shape of the pixel and may be electrically connected to the thin-film transistor.

The light-emitting element may include a light-emitting layer formed between the anode electrode and the cathode electrode. The light-emitting element may be implemented to emit light of the same color such as white light for each pixel or to emit light of a different color such as red, green, or blue for each pixel.

The encapsulation portion 130 may be disposed on the display substrate 110 so as to cover the pixel array 120.

The encapsulation portion 130 may prevent oxygen, moisture, or foreign material from invading the light-emitting layer of the pixel array 120. For example, the encapsulation portion 130 may be formed in a multi-layer structure in which an organic material layer and an inorganic material layer are alternately stacked. The present disclosure is not limited thereto.

The front portion FP of the display panel 100 may include the display substrate 110, the pixel array 120, and the encapsulation portion 130. The front portion may be formed in a flat manner except for an edge portion thereof.

The first back plate 210 to be described later may be connected or coupled to the back surface of the front portion FP so as to maintain the flat state of the front portion FP.

The bent portion BND of the display panel 100 may be free of the pixel array 120, the encapsulation portion 130, and the first back plate 210 to be described later, and may include the display substrate 110. The bent portion BND may be a portion that may be easily bent in a direction desired by the user.

The pad portion PAD of the display panel 100 may be free of the pixel array 120 and the encapsulation portion 130.

The second back plate 220 may be connected or coupled to a back surface of the pad portion PAD so that the pad portion PAD may be maintained in the flat state.

Therefore, the front portion FP of the display panel 100 may be disposed in the area in which the screen is displayed, and the pad portion PAD may be bent from the bent portion BND horizontally and inwardly and may be disposed below the front portion FP, that is, on the back surface of the front portion FP.

The first plate 210 disposed under the front surface FP of the display panel 100 and the second plate 220 disposed under the pad portion PAD may be disposed under the display substrate 110 so as to complement rigidity of the display substrate 110, and to maintain the front surface FP in the flat state.

Each of the first back plate 210 and the second back plate 220 may be formed to have a certain strength and thickness to complement the rigidity of the display substrate 110, and may not be formed in a bent portion area where the bent portion BND is disposed.

Based on a shape before the display panel 100 is bent, the first back plate 210 and the second back plate 220 may be disposed under the display substrate 110 and spaced apart from each other.

Based on a shape after the display panel 100 is bent, the first back plate 210 may be disposed under the front portion FP, and the second back plate 220 may be disposed on a top surface of the pad portion PAD.

Each of the first back plate 210 and the second back plate 220 may be a back plate disposed on the back surface of the display substrate 110.

Each of the first back plate 210 and the second back plate 220 may be composed of a plastic thin-film with rigidity.

For example, each of the first back plate 210 and the second back plate 220 may be made of polyethylene terephthalate (PET), polyimide (PI), polyethylene naphthalate (PEN), etc. The present disclosure is not limited thereto.

The first back plate 210 and the second back plate 220 may be made of the same material and may have the same thickness. The present disclosure is not limited thereto.

Based on the shape after the display panel 100 is bent, the cushion plate 300 may be disposed between the first back plate 210 and the second back plate 220.

The cushion plate 300 may be disposed under the first back plate 210.

The cushion plate 300 may include at least one of a heat-dissipation layer 310, a lift-off prevention layer 320, a cushion layer 330, and an adhesive layer 340. For example, the cushion plate 300 may have a structure in which the adhesive layer 340, the cushion layer 330, the lift-off prevention layer 320, and the heat-dissipation layer 310 are stacked downwardly sequentially.

The heat-dissipation layer 310 may be disposed in a corresponding manner to a component that generates a high temperature and may include a material with high thermal conductivity. Accordingly, a heat-dissipation effect of the display panel 100 may be improved.

The heat-dissipation layer 310 may be a conductive layer having conductivity. Accordingly, the heat-dissipation layer 310 may have a grounding function and a function of protecting the back surface of the display substrate 110 together with the heat-dissipation function.

When the heat-dissipation layer 310 is made of a metal layer, the layer 310 may effectively protect a distal end area of the display panel 100, which is vulnerable to cracks.

For example, the heat-dissipation layer 310 may include a metal having high thermal conductivity such as copper (Cu) and aluminum (Al), or graphite, or the like. The present disclosure is not limited thereto.

Further, the heat-dissipation layer 310 may include SUS (Stainless Use Steel), and may be embodied as a SUS plate.

When the heat-dissipation layer 310 includes the SUS, the layer 310 may have higher thermal conductivity and strength while having a smaller thickness, compared to a case in which the layer 310 includes other metals.

The lift-off prevention layer 320 may be disposed on the heat-dissipation layer 310.

The lift-off prevention layer 320 may be made of a flexible material such as polyimide. The present disclosure is not limited thereto.

When a side surface of the cover member 20 is bent, the cushion plate 300 may have a lifting phenomenon. For this reason, the lift-off prevention layer 320 may be disposed to prevent the lifting phenomenon.

Since the lift-off prevention layer 320 has flexibility, the layer 320 may minimize the lifting phenomenon that may otherwise occur when the cover member 20 is curved.

The cushion layer 330 may be disposed on the lift-off prevention layer 320, and may include a foam tape or a foam pad.

The cushion layer 330 may reduce the impact to various parts that may come into contact with the cushion plate 300.

The cushion layer 330 with an impact reducing function may reinforce the rigidity of the cushion plate 300.

The adhesive layer 340 may be disposed on the cushion layer 330, and may include an unevenness structure formed on a surface of the adhesive layer 340.

The unevenness structure of the adhesive layer 340 may prevent air bubbles from being generated between the first back plate 210 and the cushion plate 300 when the cushion plate 300 is attached to the first back plate 210. Thus, a degassing or defoaming process for removing air bubbles between the first back plate 210 and the cushion plate 300 may be omitted.

The adhesive layer 340 includes an adhesive component, and is in direct contact with the first back plate 210 to fix the cushion plate 300 to the first back plate 210.

The adhesive layer 340 may be made of or include a material such as at least one of OCA (Optical Clear Adhesive), OCR (Optical Clear Resin), or PSA (Pressure Sensitive Adhesive).

The second connection member 400 and the second back plate 220 may be disposed under the cushion plate 300.

The second connection member 400 may be disposed between the cushion plate 300 and the pad portion PAD.

When the pad portion PAD of the display panel 100 is bent from the bent portion BND so as to be disposed under the front portion FP of the display panel 100, a restoring force to restore the display panel 100 to a state before being bent may be strong.

When the restoring force is strongly applied, a lifting phenomenon in which the bent pad portion PAD of the display panel 100 is not fixed and is lifted off may occur.

The second connection member 400 may function as a fixing member that fixes the bent display panel 100 so that the display panel may maintain its bent shape.

The second connection member 400 may be formed to have a constant thickness in a thickness direction so as to maintain a constant curvature of the bent portion BND.

The second connection member 400 may be embodied as a double-sided tape having adhesive strength by which the member 400 may fix the second back plate 220 and the heat-dissipation layer 310 to each other. The present disclosure is not limited thereto.

Alternatively, the second connection member 400 may be made of a foam tape or a foam pad having an adhesive force so as to further have an effect of mitigating the impact.

The second back plate 220 may be disposed under the second connection member 400.

To place the second back plate 220, the second back plate 220 may be attached to the bottom surface of the pad portion PAD, and then the bent portion BND may be bent, and the second back plate 220 may be attached and fixed to the bottom surface of the second connection member 400.

In a state in which the second back plate 220 is fixed to the second connection member 400, the second back plate 220 may be disposed on a top surface of the pad portion PAD.

For example, the second connection member 400 and the second back plate 220 may be disposed between the heat-dissipation layer 310 of the cushion plate 300 and the pad portion PAD.

While the second back plate 220 is fixed to the second connection member 400, an outer portion as a top surface of the bent portion BND may be exposed to the outside, while a bottom surface as an inner portion of the bent portion BND may surface toward the side surfaces of the cushion plate 300 and the second connection member 400.

A reinforcing member 600 may be disposed on a top surface of the bent portion BND of the display panel 100.

The reinforcing member 600 may extend so as to cover the bent portion BND, and to cover at least a partial area of each of the front portion FP and the pad portion PAD.

The reinforcing member 600 may include resin. For example, the reinforcing member 600 may include UV-curable acrylic resin. The present disclosure is not limited thereto.

Since the reinforcing member 600 may cover various signal lines disposed between the encapsulation portion 130 and the pad portion PAD of the display panel 100, the member 600 may prevent moisture from invading into the signal lines while protecting the signal line from the external impact.

In order to increase the flexibility of the display panel 100, the bent portion BND may be free of other components except for the display substrate 110 and the signal lines. Thus, the reinforcing member 600 may supplement the rigidity of the bent portion BND in which the other components are absent.

In one example, the driver circuit 160 may be disposed on the other surface to one surface of the pad portion PAD of the display panel 100 on which the second back plate 220 may be disposed.

The driver circuit 160 may be disposed in a form of a chip on plastic (COP) mounted on the display substrate 110. However, the present disclosure is not limited thereto.

The driver circuit 160 may generate a data signal and a gate control signal based on image data and a timing synchronization signal supplied from an external host driving system.

The driver circuit 160 may supply a data signal to the data line of each pixel via a display pad, and may supply a gate control signal to a gate driver circuit via the display pad.

The driver circuit 160 may be mounted in a chip mounting area defined in the display substrate 110, and may be electrically connected to the display pad, and may be connected to the signal lines of the gate driver circuit and the pixel array 120 disposed on the display substrate 110.

The display pad may be disposed at a distal end of the display substrate 110 on which the driver circuit 160 is mounted.

The display pad may be disposed on one surface of the display substrate 110 and electrically connected to the flexible circuit board 500 on which a circuit board is mounted.

The flexible circuit board 500 may be electrically connected to the display pad disposed on the distal end of the display substrate 110 via a film attachment process using a conductive adhesive layer, and may be positioned on the back surface of the display panel 100.

One example of a material of the conductive adhesive layer may include an anisotropic conductive film (ACF).

The circuit board may provide the image data and the timing synchronization signal supplied from the host driving system to the driver circuit 160, and may provide a voltage required to drive each of the pixel array 120 and the gate driver circuit and the driver circuit 160.

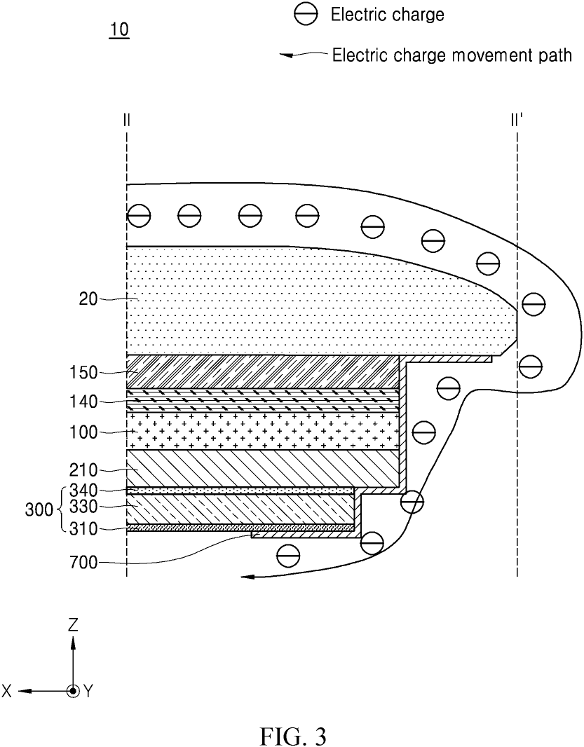

FIG. 3 shows an aspect of the present disclosure in which a charge movement path is formed using an anti-static liquid, and is a cross-sectional view in a II-II’ direction of the display device according to an aspect of the present disclosure.

The display device 10 may include an anti-static layer 700 that electrically connects the cover member 20 and the cushion plate 300 to each other.

The anti-static layer 700 may electrically connect the cover member 20 to the heat-dissipation layer 310 as the conductive layer of the cushion plate 300.

Accordingly, electric charges generated on the cover member 20 may migrate and may be dispersed along the anti-static layer 700.

Further, when the anti-static layer 700 is electrically connected to a ground through a ground path, electric charges of the cover member 20 may be discharged to the outside through the ground.

The anti-static layer 700 may be formed by applying an anti-static solution, that is, in an AS coating (anti-static coating scheme). A type of the anti-static solution is not limited to a specific type.

The anti-static layer 700 may extend from the cover member 20 along and on side surfaces of the first connection member 150, the polarizing plate 140, the display panel 100, and the first back plate 210 to the heat-dissipation layer 310 of the cushion plate 300.

The anti-static layer 700 may constitute a charge movement path along which the electric charges generated from the cover member 20 moves to the heat-dissipation layer 310 of the cushion plate 300.

Therefore, according to an aspect of the present disclosure, the concentration of an electric charges density on the display panel side surface may be reduced, thereby reducing the brighter phenomenon and greenish phenomenon that may be intensively generated in a partial area of the side surface of the display panel.

However, a separate process for applying the charging solution is required when forming the charge movement path using the anti-static solution. The efficiency of the manufacturing process may be reduced.

Further, the anti-static liquid may be applied so as to be exposed out of the display device. Thus, in a handling process of the display device, the charging solution as applied may be damaged and thus the charging function may be lost.

Further, when using the anti-static solution to form the charge movement path that electrically connects the cover member and the cushion plate to each other, the charge movement path comes into contact with the side surface of the display panel. Thus, some of the electric charges may flow into the inside of the display panel through the side surface of the display panel.

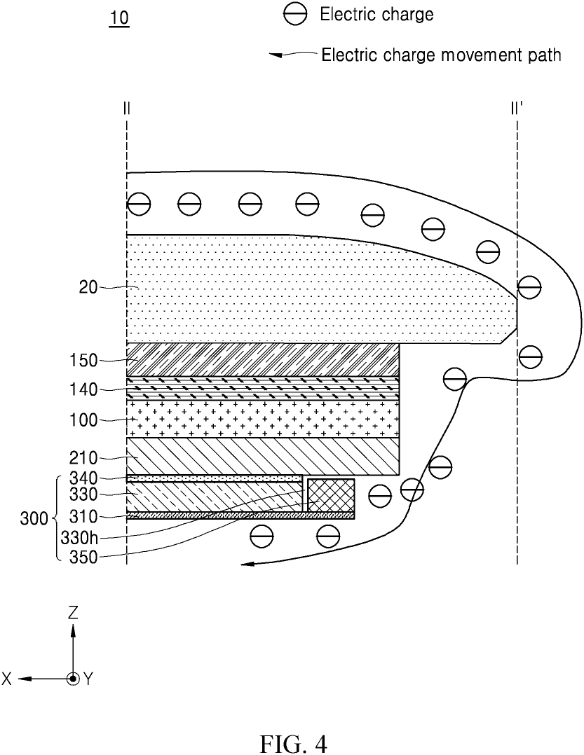

Hereinafter, with reference to FIG. 4, a display device according to another aspect of the present disclosure will be described.

FIG. 4 is a cross-sectional view in an II-II’ direction of the display device according to an aspect of the present disclosure.

Each of the layers constituting the display device shown in FIG. 4 may be shown to have a different thickness or size of each of the layers constituting the display device shown in FIG. 2 for convenience of illustration. Some layers thereof may be omitted.

The display device 10 according to an aspect of the present disclosure may include the cover member 20, the display panel 100 disposed on one surface of the cover member 20, and the cushion plate 300 disposed on one surface of the display panel 100.

The cushion plate 300 may include the adhesive layer 340, the cushion layer 330, a conductor 350, and the heat-dissipation layer 310.

The cushion layer 330 and the conductor 350 may be disposed between the display panel 100 and the heat-dissipation layer 310. The conductor 350 may be disposed in an edge area of the cushion plate 300.

The edge area of the cushion plate 300 may be an area having a predetermined width inwardly of the cushion plate 300 including a side distal end of the cushion plate 300.

The edge area of the cushion plate 300 may correspond to the non-display area NA of the display panel 100.

The conductor 350 may be disposed along at least one side surface of the cushion plate 300.

In one example, the cushion plate 300 may be formed in a flat plate shape.

When the cushion plate 300 is formed in the flat plate shape, the cushion plate 300 may have four side surfaces, and may have four edge areas respectively formed along the four surfaces.

The conductor 350 may be disposed along at least one edge area of the cushion plate 300.

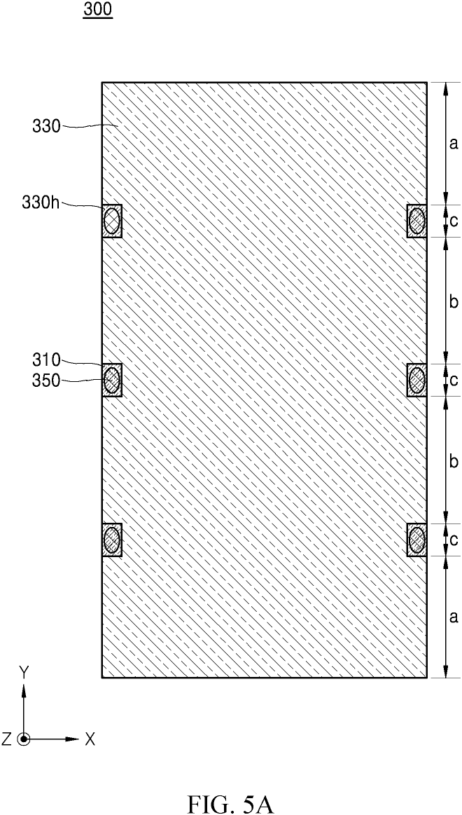

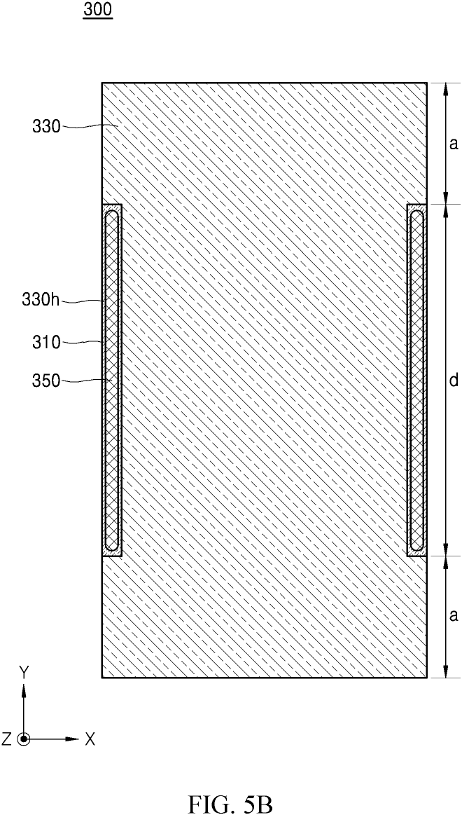

For example, referring to FIG. 5A and FIG. 5B, the conductor 350 may be disposed in each of both opposing side edge areas of cushion plate 300.

The conductor 350 may also be disposed in an upper side edge area of cushion plate 300. The conductor 350 may be further disposed in a lower side edge area thereof.

Referring to FIG. 5A, a plurality of conductors 350 may be disposed in each side edge area of the cushion plate 300.

In this case, the conductor 350 may be configured such that a plurality of conductors 350 are disposed along one side surface of the cushion plate 300.

The plurality of conductors 350 may be discontinuously arranged along one side surface of the cushion plate 300.

Further, the plurality of conductors 350 may be discontinuously arranged along at least one side surface of the cushion plate 300, for example, three side surfaces thereof except for a side surface at which the bent portion BND of the display panel 100 is disposed.

Further, referring to FIG. 5B, in each of the edge areas of the cushion plate 300, the conductor 350 may be disposed in a form of a line extending along one side surface.

For example, the conductor 350 may be formed in a line shape extending along each of the three side surfaces except for the side surface at which the bent portion BND is disposed.

In this case, the line-shaped conductor 350 extending along all of the three side surfaces of the cushion plate 300 may be discontinuously formed. However, the disclosure is not limited thereto. In another example, the line-shaped conductor 350 extending along all of the three side surfaces of the cushion plate 300 may be continuously formed.

Referring to FIG. 4, the cushion layer 330 and the conductor 350 of the cushion plate 300 may be disposed in the same layer based on the heat-dissipation layer 310.

In the edge area of the cushion layer 330, there may be one or more receiving grooves 330h in which the conductor 350 is disposed.

The receiving groove 330h of the cushion layer 330 may be formed by removing a portion of the cushion layer 330.

For example, the receiving groove 330h may extend vertically through the cushion layer 330 of the cushion plate 300.

Since the conductor 350 is inserted into the receiving groove 330h formed by partially removing the cushion layer 330, the cushion layer 330 and the conductor 350 may be disposed in the same layer based on the heat-dissipation layer 310 or may constitute the same layer.

Accordingly, the receiving groove 330h may be formed to correspond to the shape of the conductor 350.

For example, when a plurality of conductors 350 are disposed along one side surface of the cushion plate 300, a plurality of receiving grooves 330h corresponding to the plurality of conductors 350 may be formed along one side surface of the cushion plate 300.

Referring to FIG. 5A in one aspect, a length a from one distal end of the cushion plate 300 to the receiving groove 330h may be 30 µm. A length c of the receiving groove 330h may be 5 µm. A spacing b between the receiving grooves 330h adjacent to each other may be 25 µm.

In this way, as the plurality of receiving grooves 330h having a relatively short length are arranged along one side surface of the cushion plate 300, the electric charges of the cover member may be directed to the conductor 350 while maximally reducing an area in which the cushion layer 330 is removed.

Further, when the conductor 350 extends in a line shape along one side surface of the cushion plate 300, the receiving groove 330h may be formed in a line shape along one side surface of the cushion plate 300.

Referring to FIG. 5B in one aspect, a length a from one distal end of the cushion plate 300 to the receiving groove 330h may be 30 µm. A length d of the line-shaped receiving groove 330h may be 65 µm.

In this way, as the receiving groove 330h extending in a shape of a line and having a relatively large length is disposed along one side surface of the cushion plate 300, the electric charges of the cover member may be more strongly directed to the conductor 350.

The conductor 350 may have a lower resistance than that of each of the display panel 100, the polarizing plate 140, and the first back plate 210 disposed between the cover member 20 and the cushion plate 300.

For example, the conductor 350 may include a conductive material having a resistance of 10³ Ω or lower.

When the conductor 350 includes a conductive material having a resistance of 10³ Ω or lower, the electric charges generated on the cover member 20 may be directly transferred to the conductor 350 having a very low resistance while not passing through the display panel 100, the polarizing plate 140, and the first back plate 210.

The heat-dissipation layer 310 of the cushion plate 300 may be electrically connected to the low-resistance conductor 350.

According to an aspect of the present disclosure, disposing the conductor 350 in the edge area of the cushion plate 300 disposed on the back surface of the display panel 100 may allow the electric field to be induced so that the electric charges of the cover member 20 may move to the conductor 350. Thus, the charge movement path through which electric charges may travel extend from the cover member 20 to the conductor 350.

Since the conductor 350 has a relatively very low resistance than that of each of the display panel 100, the polarizing plate 140, and the first back plate 210 disposed between the cover member 20 and the cushion plate 300, the electric charges of the cover member 20 do not flow into other structures such as the display panel 100, the polarizing plate 140, and the first back plate 210, but may flow into the conductor 350, which has a very low resistance.

Therefore, according to an aspect of the present disclosure, the charge movement path may be formed in an air contact manner such that the electric charges of the cover member 20 may move to the conductor 350 while the conductor 350 is not in direct contact with the side surfaces of the cover member 20 and the display panel 100. This may reduce the electric charges of the cover member 20 from entering the inside of the display panel 100 through the side surface of the display panel 100, and allow a substantial amount of the electric charges to be effectively discharged to the outside.

Accordingly, the concentration of the electric charges on the side surface of the display panel 100 may be reduced, thereby reducing the brighter phenomenon and the greenish phenomenon that may be otherwise intensively generated in a partial area of the side surface of the display panel 100.

Further, since the conductor 350 constituting the charge movement path is received in the inside of the cushion plate 300, the loss of the charging function due to damage to the charge movement path due to external factors such as physical contact may be reduced.

Accordingly, the loss of the charging function due to damage to the charge movement path that may occur when a separate charge movement path is formed along the side surface of the display panel using the anti-static liquid may be reduced.

Further, according to an aspect of the present disclosure, since the conductor 350 constituting the charge movement path is received in the cushion plate 300, a separate additional process for forming the charge movement path after forming the cushion plate 300 is not required, so that the efficiency of the manufacturing process of the display device may be improved.

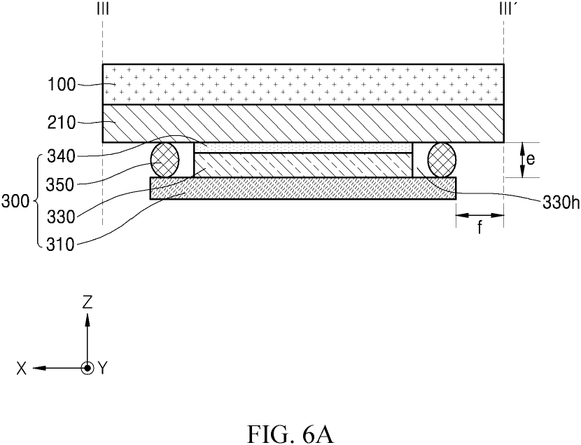

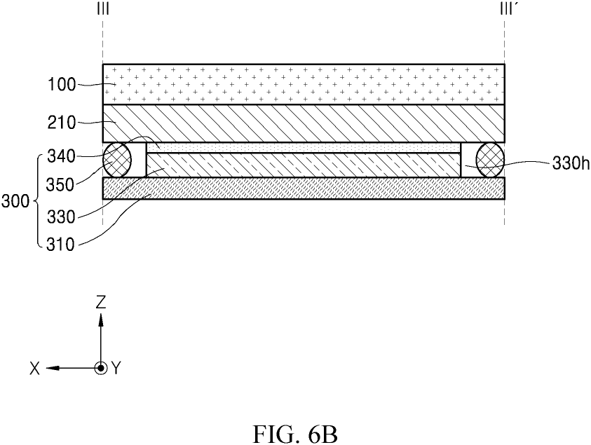

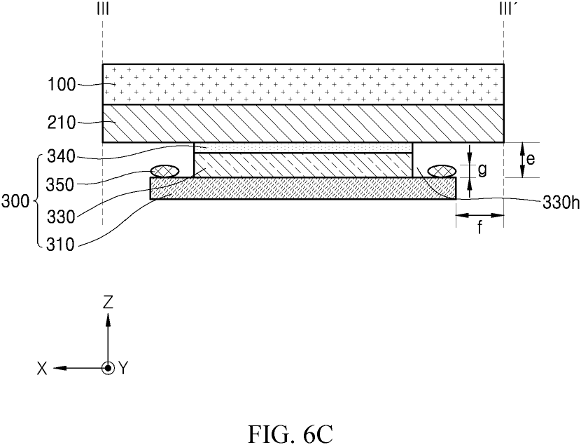

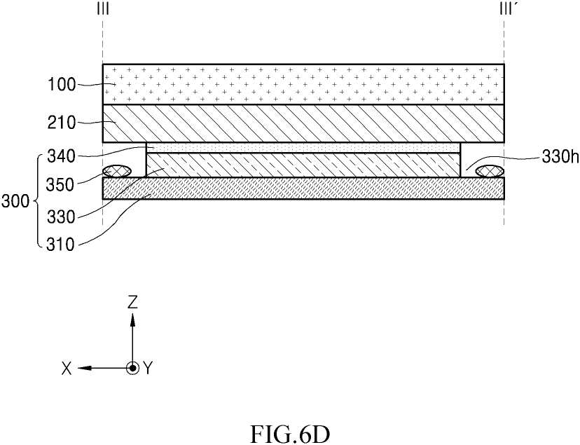

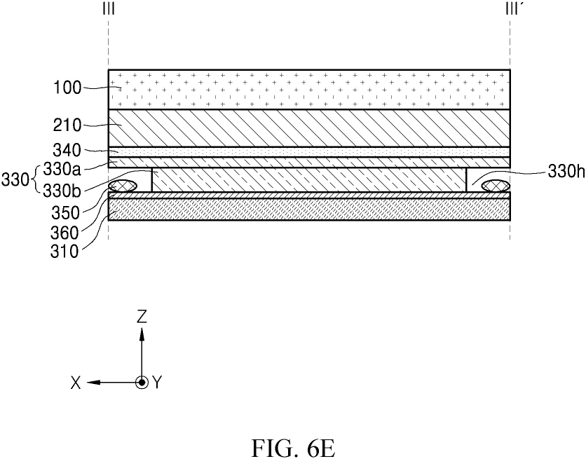

FIG. 6A to FIG. 6E are cross-sectional views in a III-III’ direction of display devices according to various aspects of the present disclosure, respectively. Hereinafter, various aspects will be described with reference to FIGS. 6A to 6E.

Referring to FIG. 6A, the back plate 210 may be disposed between the display panel 100 and the cushion plate 300. The conductor 350 may contact the back plate 210 and the heat-dissipation layer 310.

The conductor 350 which is disposed in the edge area of the cushion plate 300 and induces an electric field may allow the electric charges of the cover member 20 to move to the conductor 350 in an air contact manner. Thus, the electric charges may be discharged to the outside through the heat-dissipation layer 310 that is electrically connected to the conductor 350.

The conductor 350 also comes into contact with one surface of the back plate 210, so that the electric charges that may be generated on the back plate 210 may also be discharged to the outside through the heat-dissipation layer 310.

The conductor 350 disposed or received in the receiving groove 330h of the cushion layer 330 may be disposed to be spaced apart from the side surfaces of the cushion layer 330 and the adhesive layer 340 by a predetermined distance.

Since the conductor 350 is disposed to be spaced apart the side surfaces of the cushion layer 330 and the adhesive layer 340 by the predetermined distance while not contacting the side surfaces of the cushion layer 330 and the adhesive layer 340, an amount by which the electric charges induced on the conductor 350 are not discharged to the heat-dissipation layer 310, and thus are directed to the display panel 100 via the cushion layer 330 the adhesive layer 340 of the cushion plate 300 may be reduced.

The distal end of the cushion plate 300 may be disposed inwardly of the distal end of the display panel 100. Therefore, the conductor 350 of the cushion plate 300 may be disposed inwardly of the distal end of the display panel 100.

Since the conductor 350 which is disposed in the edge area of the cushion plate 300 and induces the electric field may direct the electric charges of the cover member 20 to the conductor 350 in the air contact manner, the electric charges of the cover member 20 may be guided to the conductor 350 even when the distal end of the conductor 350 is disposed inwardly of the distal end of the display panel 100.

Therefore, a distance between the conductor 350 and the side surface of the display panel 100 may be further increased. Thus, a distance between the charge movement path extending from the cover member 20 to the conductor 350 and the side surface of the display panel 100 may be further increased.

Accordingly, an amount by which the electric charges moving through the charge movement path are not guided to the conductor 350, but deviate from the path and are guided to the display panel 100 may be reduced.

In order to increase conductivity of connection between the heat-dissipation layer 310 and the conductor 350, a separate adhesive layer may not be formed so that the heat-dissipation layer 310 and the conductor 350 directly contact each other.

In this case, the conductor 350 itself may include a material having an adhesive component while having conductivity, so that the conductor 350 may be fixedly in contact with the heat-dissipation layer 310 without a separate adhesive layer.

Referring to FIG. 6A in an aspect, a vertical dimension e of the conductor 350 may be 90 µm. In this case, a thickness of the adhesive layer 340 of the cushion plate 300 may be 30 µm, a thickness of the cushion layer 330 may be 60 µm, and a thickness of the heat-dissipation layer 310 may be 90 µm.

The vertical dimension of the conductor 350 may be equal to a distance between the heat-dissipation layer 310 and the back plate 210, so that the conductor 350 may contact both the heat-dissipation layer 310 and the back plate 210.

Further, when the distal end of the cushion plate 300 is disposed inwardly of the distal end of display panel 100, a distance f from one distal end of the back plate 210 to one distal end of the heat-dissipation layer 310 may be smaller than or equal to 400 µm.

According to an aspect of the present disclosure, the electric charges of the cover member may be directed to the conductor 350 of the cushion plate 300 in the air contact manner. Thus, even when the distal end of the cushion plate 300 is positioned inwardly of the distal end of the display panel 100, the electric charges of the cover member may be effectively directed thereto.

When the distance f from one distal end of the back plate 210 to one distal end of the heat-dissipation layer 310 exceeds 400 µm, the electric charges of the cover member 20 may not be directed to the conductive 250 in the air contact manner.

In one example, referring to FIG. 6B, the distal end of the cushion plate 300 may coincide with the distal end of display panel 100.

Therefore, the distal end of the heat-dissipation layer 310 coincides with the distal end of the display panel 100, and the distal end of the cushion layer 330 may be disposed inwardly of the distal end of the display panel 100.

Since the distal end of the heat-dissipation layer 310 coincides with the distal end of the display panel 100, the conductor 350 may be positioned closer to the distal end of the display panel 100.

Accordingly, in the aspect according to FIG. 6B, a distance between the conductor 350 and the cover member 20 may be smaller, compared to that in the aspect according to FIG. 6A. Thus, a size of the conductor 350 for maintaining the charge movement path via air contact between the cover member 20 and the conductor 350 may be relatively reduced.

When the size of the conductor 350 is reduced, a size of the cushion layer 330 may be increased by the reduced area. Thus, the cushion function of cushion plate 300 may be enhanced.

Referring to FIG. 6C and FIG. 6D, the conductor 350 may be disposed to be spaced apart from the back plate 210 by a predetermined distance in a vertical direction.

Accordingly, the conductor 350 may contact the heat-dissipation layer 310 while not contacting the back plate 210.

According to an aspect of the present disclosure, the conductor 350 that is disposed in the edge area of the cushion plate 300 and induces an electric field may direct the electric charges of the cover member 20 to the conductor 350 in the air contact manner. Thus, even when the conductor 350 does not contact the back plate 210 and is spaced apart therefrom by a predetermined distance, the charge movement path may be formed.

When the conductor 350 comes into contact with the back plate 210, some of the electric charges induced on the conductor 350 may flow to the back plate 210 and then to the display panel 100.

However, referring to an aspect of the present disclosure in which the conductor 350 is in contact with the heat-dissipation layer 310 but is not in contact with the back plate 210, the electric charges induced on the conductor 350 may be guided to the heat-dissipation layer 310 while not flowing to the back plate 210, and then may be effectively discharged to the outside.

Referring to FIG. 6D, in one aspect, a vertical dimension g of the conductor 350 may be 60 µm or smaller. In this case, the thickness of the adhesive layer 340 of the cushion plate 300 may be 30 µm, the thickness of the cushion layer 330 may be 60 µm, and the thickness of the heat-dissipation layer 310 may be 90 µm.

The vertical dimension of the conductor 350 may be smaller than a distance between the heat-dissipation layer 310 and the back plate 210 and may be smaller than the thickness of the cushion layer 330, so that the conductor 350 may contact the heat-dissipation layer 310 while not contacting the back plate 210.

Further, when the distal end of the cushion plate 300 is disposed inwardly of the distal end of the display panel 100, the distance f from one distal end of the back plate 210 to one distal end of the heat-dissipation layer 310 may be 400 µm or smaller.

According to an aspect of the present disclosure, the electric charges of the cover member may be directed to the conductor 350 of the cushion plate 300 in the air contact manner. Thus, even when the distal end of the cushion plate 300 is positioned inwardly of the distal end of the display panel 100, the electric charges of the cover member may be effectively directed thereto.

When the distance f from one distal end of the back plate 210 to one distal end of the heat-dissipation layer 310 exceeds 400 µm, the electric charges of the cover member 20 may not be directed to the conductive 250 in the air contact manner.

Referring to FIG. 6E, the cushion layer 330 may include a first cushion layer 330a and a second cushion layer 330b. The second cushion layer 330b may be disposed between the first cushion layer 330a and the heat-dissipation layer 310.

A distal end of the second cushion layer 330b may be disposed inwardly of a distal end of the first cushion layer 330a, and the conductor 350 may be disposed between the first cushion layer 330a and the heat-dissipation layer 310.

For example, the receiving groove 330h of the cushion layer 330 into which the conductor 350 is inserted may not extend through an entirety of an area of the cushion layer 330 corresponding to the receiving groove 330h, but may be formed by removing only a portion of the cushion layer 330.

As described with reference to FIG. 6C and FIG. 6D, according to an aspect of the present disclosure, the conductor 350 that is disposed in the edge area of the cushion plate 300 and induces the electric field may allow the electric charges of the cover member 20 to move to the conductor 350 in the air contact manner. Thus, even when the conductor 350 does not contact the back plate 210 and is spaced apart therefrom by a predetermined distance, the charge movement path may be formed.

Therefore, although the thickness of the conductor 350 is not large enough to contact the back plate 210, the charge movement path may be formed.

Accordingly, the receiving groove 330h may vertically extend through only a portion of the cushion layer 330 but may not vertically extend through the remainder of the cushion layer 330. In other words, the receiving groove 330h may extend through the edge area of the second cushion layer 330b disposed on the back surface of the first cushion layer 330a, but may not extend through the first cushion layer 330a. The conductor 350 may be received into the receiving groove 330h. Thus, an amount by which the cushion layer 330 is removed may be reduced.

In this way, an amount by which the cushion layer 330 is removed may be reduced while maintaining the charge movement path, so that the cushion function of the cushion layer 330 may not be deteriorated.

An additional conductive layer 360 may be disposed between the cushion layer 330 and the heat-dissipation layer 310.

The conductive layer 360 may include a conductive pressure sensitive adhesive (PSA) that includes an adhesive component.

For example, the conductive layer 360 may be disposed on the other surface of the heat-dissipation layer 310, and the conductor 350 may contact the conductive layer 360.

Accordingly, while the conductor 350 is fixed to the heat-dissipation layer 310 via the conductive layer 360, the electric connection thereof the heat-dissipation layer 310 may not be weakened and the charge movement path may be maintained.

A first aspect of the present disclosure provides a display device comprising: a cover member; a display panel disposed on one surface of the cover member; and a cushion plate disposed on one surface of the display panel, wherein the cushion plate includes a cushion layer, a conductor, and a heat-dissipation layer, wherein the cushion layer and the conductive layer are disposed between the display panel and the heat-dissipation layer, wherein the conductor is disposed in an edge area of the cushion plate.

In one implementation of the first aspect, the cushion layer and the conductor are disposed in the same layer based on the heat-dissipation layer.

In one implementation of the first aspect, the conductor is disposed along at least one edge area of the cushion plate, wherein the conductor includes a plurality of conductors arranged along each edge area of the cushion plate.

In one implementation of the first aspect, the conductor is disposed along at least one edge area of the cushion plate, wherein the conductor disposed in each edge area of the cushion plate extends in a line shape.

In one implementation of the first aspect, at least one receiving groove is defined in an edge area of the cushion layer, wherein the conductor is received in the groove.

In one implementation of the first aspect, the receiving groove is formed by removing a portion of the cushion layer.

In one implementation of the first aspect, a back plate is disposed between the display panel and the cushion plate, wherein the conductor is in contact with the back plate and the heat-dissipation layer.

In one implementation of the first aspect, the conductor is in contact with the heat-dissipation layer.

In one implementation of the first aspect, a distal end of the cushion plate is disposed inwardly of a distal end of the display panel.

In one implementation of the first aspect, a distal end of the cushion plate coincides with a distal end of the display panel.

In one implementation of the first aspect, a distal end of the heat-dissipation layer coincides with the distal end of the display panel, while a distal end of the cushion layer is disposed inwardly of the distal end of the display panel.

In one implementation of the first aspect, the cushion layer includes a first cushion layer and a second cushion layer, wherein the second cushion layer is disposed between the first cushion layer and the heat-dissipation layer, wherein a distal end of the second cushion layer is disposed inwardly of a distal end of the first cushion layer, wherein the conductor is disposed between the first cushion layer and the heat-dissipation layer.

In one implementation of the first aspect, a conductive layer is disposed on the other surface of the heat-dissipation layer, wherein the conductor is in contact with the conductive layer.

In one implementation of the first aspect, the conductor is disposed to be spaced apart from the cushion layer by a predetermined distance.

A second aspect of the present disclosure provides a display device comprising: a cover member; a display panel disposed on one surface of the cover member; and a cushion plate disposed on one surface of the display panel, wherein the cushion plate includes at least one conductor having a lower electrical resistance than an electrical resistance of the display panel, wherein the at least one conductor is disposed in an edge area of the cushion plate.

In one implementation of the second aspect, the resistance of the conductor is lower than or equal to 10³ Ω.

In one implementation of the second aspect, the conductor is disposed inwardly of a distal end of the display panel.

In one implementation of the second aspect, the cushion plate includes a heat-dissipation layer, and a cushion layer disposed between the heat-dissipation layer and the display panel, wherein the heat-dissipation layer and the conductor are electrically connected to each other.

In one implementation of the second aspect, a back plate is disposed between the display panel and the cushion plate, wherein the conductor is vertically spaced apart from the back plate by a predetermined vertical distance.

A third aspect of the present disclosure provides a display apparatus comprising: the display device as above defined; and a casing disposed on the back surface of the display device so as to support the cover member.

Although the aspects of the present disclosure have been described above in more detail with reference to the accompanying drawings, the present disclosure is not necessarily limited to the aspects, and various modifications may be made within the scope that does not deviate from the technical spirit of the present disclosure. Therefore, the aspects as disclosed in the present disclosure are to illustrate the disclosure rather than limiting the technical idea of the present disclosure, and the scope of the technical idea of the present disclosure is not limited to the aspects. Therefore, it should be understood that the aspects as described above are illustrative in all respects and not restrictive. The protective scope of the present disclosure should be interpreted based on the claims, and all technical ideas within the scope equivalent thereto should be construed as being included in the scope of the present disclosure.

What is claimed is:

1. A display device comprising:
a cover member;
a display panel disposed on the cover member; and
a cushion plate disposed on the display panel,
wherein the cushion plate includes a cushion layer, a conductor, and a heat-dissipation layer,
wherein the cushion layer and the conductor are disposed between the display panel and the heat-dissipation layer, and
wherein the conductor is disposed in an edge area of the cushion plate.

2. The display device of claim 1, wherein the cushion layer and the conductor are disposed at a same layer with respect to the heat-dissipation layer.

3. The display device of claim 1, wherein the conductor is disposed along at least one edge area of the cushion plate, and
wherein the conductor includes a plurality of conductors arranged along each edge area of the cushion plate.

4. The display device of claim 1, wherein the conductor is disposed along at least one edge area of the cushion plate, and
wherein the conductor disposed in each edge area of the cushion plate extends in a line shape.

5. The display device of claim 1, wherein at least one receiving groove is defined in an edge area of the cushion layer, and
wherein the conductor is disposed in the at least one receiving groove.

6. The display device of claim 5, wherein the at least one receiving groove is formed by removing a portion of the cushion layer.

7. The display device of claim 1, further comprising a back plate disposed between the display panel and the cushion plate,
wherein the conductor is in contact with the back plate and the heat-dissipation layer.

8. The display device of claim 1, wherein the conductor is in contact with the heat-dissipation layer.

9. The display device of claim 1, wherein a distal end of the cushion plate is disposed inwardly of a distal end of the display panel.

10. The display device of claim 1, wherein a distal end of the cushion plate coincides with a distal end of the display panel.

11. The display device of claim 10, wherein a distal end of the heat-dissipation layer coincides with the distal end of the display panel, while a distal end of the cushion layer is disposed inwardly of the distal end of the display panel.

12. The display device of claim 1, wherein the cushion layer includes a first cushion layer and a second cushion layer,
wherein the second cushion layer is disposed between the first cushion layer and the heat-dissipation layer,
wherein a distal end of the second cushion layer is disposed inwardly of a distal end of the first cushion layer, and
wherein the conductor is disposed between the first cushion layer and the heat-dissipation layer.

13. The display device of claim 12, further comprising a conductive layer disposed on the heat-dissipation layer,
wherein the conductor is in contact with the conductive layer.

14. The display device of claim 1, wherein the conductor is spaced apart from the cushion layer by a predetermined distance.

15. A display device comprising:
a cover member;
a display panel disposed on the cover member; and
a cushion plate disposed on the display panel,
wherein the cushion plate includes at least one conductor having an electrical resistance lower than an electrical resistance of the display panel, and
wherein the at least one conductor is disposed in an edge area of the cushion plate.

16. The display device of claim 15, wherein the resistance of the conductor is lower than or equal to 10³ Ω.

17. The display device of claim 15, wherein the conductor is disposed inwardly of a distal end of the display panel.

18. The display device of claim 15, wherein the cushion plate includes a heat-dissipation layer, and a cushion layer disposed between the heat-dissipation layer and the display panel, and
wherein the heat-dissipation layer and the conductor are electrically connected to each other.

19. The display device of claim 15, further comprising a back plate disposed between the display panel and the cushion plate,
wherein the conductor is vertically spaced apart from the back plate by a predetermined vertical distance.

20. A display device comprising:
a cover member;
a display panel disposed on the cover member;
a cushion plate disposed on the display panel and including a cushion layer, a conductor, and a heat-dissipation layer, wherein the cushion layer and the conductive layer are disposed between the display panel and the heat-dissipation layer, and the conductor is disposed in an edge area of the cushion plate; and
a casing disposed on the back surface of the display device so as to support the cover member.
